(19) United States
(12) Patent Application Publication
(10) Pub. No.: US 2017/0175025 A1
(43) Pub. Date: Jun. 22, 2017

(54) SOLID LUBRICANT IN THE FORM OF FILM COMPRISING TRIAZINE COMPOUND OR SALT THEREOF

(71) Applicant: KYODO YUSHI CO., LTD., Fujisawa-shi (JP)

(72) Inventor: Takashi HANZAWA, Yamato-shi (JP)

(73) Assignee: KYODO YUSHI CO., LTD., Fujisawa-shi (JP)

(21) Appl. No.: 15/386,839

(22) Filed: Dec. 21, 2016

(30) Foreign Application Priority Data
Dec. 22, 2015 (JP) 2015-250106

(51) Int. Cl. C10M 133/42; C23C 14/24; C23C 14/12; C09D 5/00

(52) U.S. Cl. CPC C10M 133/42; C09D 5/00; C23C 14/24; C23C 14/12; C10M 2215/222; C10N 2250/10; C10N 2250/08

(57) ABSTRACT

The invention provides a solid lubricant in the form of film containing a triazine compound or the salt thereof, such as melamine cyanurate or the like.

### TECHNICAL FIELD

The present invention relates to a solid lubricant in the form of film with lubricating properties, comprising a triazine compound or the salt thereof.

### BACKGROUND ART

In the conventional technical field of lubricant, the triazine compounds or salts thereof have been generally used as the antioxidant, metal corrosion inhibitor or preservative, as disclosed in WO 2006-078035 A, JP 2002-285186 A, JP 2002-285182 and the like.

In the food packaging field, on the other hand, it is known that the triazine compounds or the salts thereof can be applied to a base material such as a polyethylene terephthalate film, polypropylene film or the like to form a barrier film against oxygen, as disclosed in JP 2002-518219 A.

However, it has not been known to use a coating film of the triazine compound or the salt thereof as the lubricant.

### SUMMARY OF INVENTION

### Technical Problem

An object of the invention is to provide a lubricant in the form of film made of an organic substance.

### Solution to Problem

Melamine cyanurate, one of the typical triazine compounds shows a mica-like crystalline structure. Melamine cyanurate has been used as a solid lubricant. Surprisingly, the inventor of the present invention found that a solid lubricant in the form of film produced from melamine cyanurate can exhibit excellent lubricating properties. The present invention has been thus accomplished on the above-mentioned findings. Accordingly, the present invention provides;

1. A solid lubricant in the form of film comprising a triazine compound or a salt thereof.

2. The solid lubricant in the form of film of the item 1, wherein the triazine compound or the salt thereof is melamine cyanurate.

3. The solid lubricant in the form of film of the item 1 or 2, which is formed by physical vapor deposition.

4. The solid lubricant in the form of film of the item 3, wherein the physical vapor deposition is vacuum deposition.

5. A lubricant prepared by forming a layer of a grease or lubricating oil on the solid lubricant in the form of film of any one of the items 1 to 4.

6. A method for making a solid lubricant in the form of film, comprising the step of forming a film of a triazine compound or a salt thereof by deposition.

### Effects of Invention

The invention can provide a lubricant in the form of film made of an organic substance. The lubricant of the invention can achieve lubrication under extremely low temperatures and high temperatures, and also can complete lubrication under a clean environment without contaminating the surroundings unlike the lubricating oil or grease, and can be introduced without changing the dimensions of the related parts.

### DESCRIPTION OF EMBODIMENTS

Examples of the triazine compounds or the salts thereof capable of forming a solid lubricant in the form of film according to the invention include 1,3,5-triazine, such as melamine, ameline, amelide, cyanuric acid, 2-ureidemelamine, melam, melem, and melon. Examples of the melamine salt include melamine cyanurate (MCA), melamine phosphate, dimelamine pyrophosphate or melamine polyphosphate, and functionalized melamine such as hexamethoxymethyl melamine or acrylate-functionalized melamine. In particular, melamine cyanurate is preferred.

The triazine compounds or the salts thereof as mentioned above may be used alone or two or more kinds may be used in combination. When the triazine compounds or the salts thereof are used in combination, two or more kinds of triazine compounds or the salts thereof may be contained in a single coating film. Alternatively, a plurality of coating films may be used, each comprising one kind of triazine compound or the salt thereof alone.

The coating film of the invention may further comprise other compounds in addition to the triazine compound or the salt thereof. Examples of such additional compounds include molybdenum disulfide, tungsten disulfide, boron nitride, and PTFE. In the case where other compounds are used in addition to the triazine compound or the salt thereof, the triazine compound or the salt thereof may preferably be contained in an amount of at least 75 mass %, more preferably at least 90 mass %, and most preferably 100 mass %, based on the total mass of the coating film.

The triazine coating film according to the invention may directly be formed on the portion to be lubricated. The triazine coating film according to the invention may be used together with at least one selected from the group consisting of water, oil and grease. The material constituting the portion on which the triazine coating film can be formed may be metals, e.g., iron, copper, silver, zinc, chromium, aluminum and the like, glass, ceramic, rubber, and plastic materials, i.e., so-called engineering plastics such as polyamide, polyacetal, polycarbonate and the like.

The triazine compound or the salt thereof may be applied using the known techniques and apparatus of deposition. The deposition temperature, which varies depending on the pressure may preferably be lower than the decomposition temperature of the triazine compound or the salt thereof, more preferably 600° C. or less, and still more preferably 500° C. or less. The deposition temperature may preferably be 300° C. or more, and more preferably 400° C. or more. The deposition can be conducted under high pressure or atmospheric pressure, but preferably under reduced pressure, for example 1,000 Pa or less, preferably 100 Pa or less, more preferably in the range of 10 to 10⁻⁴ Pa, and most preferably in the range of 1 to 5×10⁻³ Pa.

When the coating film is formed by deposition, physical vapor deposition is preferable. The methods of physical vapor deposition such as vacuum deposition, sputtering, and ion plating are available, but vacuum deposition is particularly preferred.

If the thickness of a coating film constituting the lubricant according to the invention is at least of the submicron order, the coating film can serve as a lubricant. For example, the thickness of 0.1 μm or more is sufficient. The upper limit of the thickness is not particularly limited, but may preferably be 10 to 5 μm.

The lubricant of the invention may be applied to any portions where a coating film of the triazine compound or the salt thereof can be formed, for example, to plain bearings, rolling bearings, gears, screws, automotive parts, electrical and electronic equipment and the like.

### EXAMPLES

### Example 1

A vacuum deposition apparatus (VED-1554, made by Akashi Seisakusho) equipped with a vacuum chamber and a tungsten filament for deposition (i.e., filament helically coiled into a basket form) was used. Melamine cyanurate was placed in the coiled tungsten filament. The filament was heated to 400 to 500° C., with the pressure of the vacuum chamber reduced to 5×10⁻³ Pa to 1 Pa. Thus, melamine cyanurate was evaporated and deposited onto a substrate of single crystal potassium bromide.

The IR spectrum of the deposited melamine cyanurate film was compared with that of the melamine cyanurate before deposition. It was confirmed that the chemical structure of the melamine cyanurate was not changed after deposition.

### Example 2

### Determination of the Coefficient of Friction by Barbell—Plate Test

Deposited films of Example 2 and Comparative Example 2 were prepared in the same manner as in Example 1 except that melamine cyanurate or a mineral oil having a kinematic viscosity of 100 mm²/s at 25° C. was deposited onto the test pieces below instead of the substrate of single crystal potassium bromide. The test pieces without deposition were used as Comparative Example 3.

This is an experiment where a plate is brought in sliding contact with the surface of a barbell (a test piece in a barbell form) by rotating a plate (a test piece in a plate form) with the application of a load, with the surface of the plate in contact with the barbell. The barbell is made of Fe—Cr alloy steel, and has two discs, each having a diameter of 13 mm and a thickness of 5 mm and a shaft connecting the center portions of the two discs. The plate is designed to come in sliding contact with the peripheries of the discs of the barbell.

### (1) Materials of Test Pieces

Test piece in a barbell form: SCr415

Test piece in a plate form: SUJ2

### (2) Test Method

In the test, the linear contact with the cylindrical form allows a stable contact with little unevenness even at relatively low contact pressure. The test conditions are shown in Table 1. The frictional coefficient was determined by measuring the torque in the sliding direction using a load cell.

### (3) Test Conditions

Contact pressure: 210 MPa

Sliding velocity: 0.1 m/s

Time duration: five minutes

TABLE 1

| | | Comparative | Comparative |
|---|---|---|---|
| | Example 2 | Example 2 | Example 3 |
| Deposited film | MCA | Mineral oil | Not lubricated |
| | | (100 mm²/s at 25° C.) | |
| Coefficient of | 0.2 | 0.35 | >1 |
| friction (average) | | | |
| obtained as the test | | | |
| results | | | |

1. A solid lubricant in the form of film comprising a triazine compound or a salt thereof.

2. The solid lubricant in the form of film of claim 1, wherein the triazine compound or the salt thereof is melamine cyanurate.

3. The solid lubricant in the form of film of claim 1, which is formed by physical vapor deposition.

4. The solid lubricant in the form of film of claim 3, wherein the physical vapor deposition is vacuum deposition.

5. A lubricant prepared by forming a layer of a grease or lubricating oil on the solid lubricant in the form of film of claim 1.

6. A method for making a solid lubricant in the form of film, comprising the step of forming a film of a triazine compound or a salt thereof by deposition.
